(19) United States
(12) Patent Application Publication
(10) Pub. No.: US 2023/0214546 A1
(43) Pub. Date: Jul. 6, 2023

(54) Method and System for Global Stabilization Control of Hypersonic Vehicle

(71) Applicant: Beijing Institute of Technology, Beijing (CN)

(72) Inventors: Yanjun Zhang, Bejing (CN); Jian Sun, Beijing (CN)

(73) Assignee: Beijing Institute of Technology, Beijing (CN)

(21) Appl. No.: 17/683,887

(22) Filed: Mar. 1, 2022

(30) Foreign Application Priority Data
Dec. 31, 2021 (CN) 202111663061.2

(51) Int. Cl. G06F 30/15

(52) U.S. Cl. CPC G06F 30/15; B64C 30/00

(57) ABSTRACT

Method and system for global stabilization control of a hypersonic vehicle. The method can include constructing a longitudinal dynamic model of a non-minimum phase hypersonic vehicle; translating a non-zero equilibrium point of the hypersonic vehicle to the origin of coordinates by transformation of coordinates to transform the longitudinal dynamic model, where the transformed longitudinal dynamic model includes an output dynamic model and an internal dynamic model; performing variable decomposition on the transformed longitudinal dynamic model by state decomposition and constructing an auxiliary system model using decomposed variables, where the auxiliary system model includes output dynamics and internal dynamics; and determining a control law based on a feedback linearization theory according to the output dynamics and realizing the global stabilization control of the hypersonic vehicle with the control law. The present disclosure enables the global stabilization control of a non-minimum phase hypersonic vehicle.

### CROSS REFERENCE TO RELATED APPLICATION

This patent application claims the benefit and priority of Chinese Patent Application No. 202111663061.2, filed on Dec. 31, 2021, the disclosure of which is incorporated by reference herein in its entirety as part of the present application.

### TECHNICAL FIELD

The present disclosure relates to the technical field of aerial vehicle control, and in particular, to a method and system for global stabilization control of a hypersonic vehicle.

### BACKGROUND

The global stabilization of a longitudinal dynamic system of a typical non-minimum phase (i.e., unstable internal system dynamics) hypersonic vehicle is always a difficult problem in the area of control applications. Several representative theoretical design methods for non-minimum phase systems have been proposed in the area of control theories, but most of them require that internal dynamics should meet specific structure matching conditions. As an internally famous control study scholar, Professor Isidori proposed a promising stabilization method for a nonlinear non-minimum phase system in 2000: the stabilization of a single-input single-output non-minimum phase system is realized based on a method of constructing a dynamic compensator. Although it has been proposed in this method that a dynamic compensator can effectively deal with non-minimum phase and realize system stabilization, the following key condition is assumed as basis: the system is shifted to the minimum phase after the introduction of the dynamic compensator and the redefinition of virtual input and output. Actually, the construction method and the analytical form of a dynamic compensator are not presented. So far, no existing result has provided a specific design method for a dynamic compensator, and it has not been confirmed whether the assumption that the dynamically compensated system is stabilizable is true or under what conditions the assumption is certainly true.

Accordingly, the global stabilization control of a hypersonic vehicle with non-minimum phase property needs to be further perfected.

### SUMMARY

An objective of the present disclosure is to provide a method and system for global stabilization control of a non-minimum phase hypersonic vehicle which can achieve global stabilization of the non-minimum phase hypersonic vehicle.

To achieve the above purpose, the present disclosure provides the following technical solutions:

A method for global stabilization control of a hypersonic vehicle includes:

constructing a longitudinal dynamic model of a non-minimum phase hypersonic vehicle, where the longitudinal dynamic model uses an elevator angle and a throttle opening as input signals, and a speed and a flight path angle of the hypersonic vehicle as output signals;

translating a non-zero equilibrium point of the hypersonic vehicle to the origin of coordinates by transformation of coordinates to transform the longitudinal dynamic model, wherein the transformed longitudinal dynamic model comprises an output dynamic model and an internal dynamic model;

performing variable decomposition on the transformed longitudinal dynamic model by state decomposition and constructing an auxiliary system model using decomposed variables, wherein the auxiliary system model comprises output dynamics and internal dynamics; and

determining a control law based on a feedback linearization theory according to the output dynamics and realizing the global stabilization control of the hypersonic vehicle with the control law.

Optionally, the constructing a longitudinal dynamic model of a non-minimum phase hypersonic vehicle specifically involves the following Formulas:

$$\dot{V} = \frac{T cosα - D}{m} - g sinγ .$$

$$\dot{γ} = \frac{L + T sinα}{mV} - \frac{g}{V} cosγ ,$$

$$\dot{θ} = q ,$$

$$\dot{q} = \frac{{M}_{yy}}{{I}_{yy}} ,$$

where V represents a speed of the hypersonic vehicle, while γ a flight path angle, q a pitch rate, θ an Euler angle, meeting the relation θ=γ+α with α being an angle of attack, [V, γ, θ, q]^{T} a state vector, T, L, D a thrust, a lift, and a drag, respectively, M_{yy} a pitching moment, m a mass of the hypersonic vehicle, g the gravitational acceleration, and I_{yy} an inertia moment.

Optionally, the translating a non-zero equilibrium point of the hypersonic vehicle to the origin of coordinates by transformation of coordinates to transform the longitudinal dynamic model specifically involves the following Formulas:

\dot{x}₁=f₁+g₁₂u₂, \dot{x}₂=f₂+g₂₁u₁+g₂₂u₂, \dot{x}₃=x₄, \dot{x}₄=f₃+g₃₁u₁+g₃₂u₂,

where x₁ [symbol] x₂ [symbol] x₃ [symbol] x₄ correspondingly take the place of V [symbol] γ [symbol] θ [symbol] q; x₁ and x₂ are output signals, u₁ and u₂ are input signals, and f₁, f₂, f₃, g₁₂, g₂₂, and g₃₂ are coefficients of the transformed longitudinal dynamic model, respectively.

Optionally, the performing variable decomposition on the transformed longitudinal dynamic model by state decomposition and constructing an auxiliary system model using decomposed variables specifically involves the following Formulas:

$${\dot{s}}_{1} = {f}_{1} + {g}_{12} {u}_{2} - {\dot{N}}_{1} ,$$

$${\dot{s}}_{2} = {f}_{2} + {g}_{21} {u}_{2} + {g}_{22} {u}_{2} - {\dot{N}}_{2} ,$$

$${\dot{x}}_{3} = {x}_{4} ,$$

$${\dot{x}}_{4} = {f}_{3} + \frac{{g}_{31}}{{g}_{21}} ( {\dot{s}}_{2} - {\dot{N}}_{2} - {f}_{2} ) + \frac{{g}_{32} {g}_{21} - {g}_{31} {g}_{22}}{{g}_{12} {g}_{21}} ( {\dot{s}}_{1} + {\dot{N}}_{1} - {f}_{1} ) ,$$

where s₁, s₂ are output signals; N₁ and N₂ are designed compensation control signals, with

$${\dot{N}}_{1} = - {γ}_{1} {N}_{1} + {f}_{1} - \frac{{g}_{12} {g}_{21}}{{g}_{32} {g}_{21} - {g}_{31} {g}_{22}} ( {f}_{3} + {λ}_{11} {x}_{4} + {λ}_{10} {x}_{3} + \frac{{g}_{31}}{{g}_{21}} ( - {μ}_{2} {s}_{2} - {γ}_{2} {N}_{2} - {f}_{2} ) )$$

and \dot{N}₂=−γ₂N₂; γ₁, γ₂, λ₁₁, and λ₁₀ are all constant coefficients, with γ₁ and γ₂ being greater than zero and λ₁₁ and λ₁₀ meeting a stable polynomial z²+λ₁₁z+λ₁₀ with respect to z; and g₂₁ and g₃₁ are model coefficients.

Optionally, the determining a control law based on a feedback linearization theory according to the output dynamics and realizing the global stabilization control of the hypersonic vehicle with the control law specifically involve the following Formula:

$$[ \begin{matrix}{u}_{1} \\ {u}_{2}\end{matrix} ] = {G}^{- 1} [ \begin{matrix}- {f}_{1} - {μ}_{1} {x}_{1} + {μ}_{1} {N}_{1} + {\dot{N}}_{1} \\ - {f}_{2} - {μ}_{2} {x}_{2} + {μ}_{2} {N}_{2} + {\dot{N}}_{2}\end{matrix} ] ,$$

where G is an output coefficient matrix.

A system for global stabilization control of a hypersonic vehicle includes: a longitudinal dynamic model constructing module, configured to construct a longitudinal dynamic model of a non-minimum phase hypersonic vehicle, wherein input signals to the longitudinal dynamic model are an elevator angle and a throttle opening, and output signals thereof are a speed and a flight path angle of the hypersonic vehicle; a longitudinal dynamic model transforming module, configured to translate a non-zero equilibrium point of the hypersonic vehicle to the origin of coordinates by transformation of coordinates to transform the longitudinal dynamic model, wherein the transformed longitudinal dynamic model comprises an output dynamic model and an internal dynamic model; an auxiliary system model constructing module, configured to perform variable decomposition on the transformed longitudinal dynamic model by state decomposition and construct an auxiliary system model using decomposed variables, wherein the auxiliary system model comprises output dynamics and internal dynamics; and a control law determining module, configured to determine a control law based on a feedback linearization theory according to the output dynamics and realize the global stabilization control of the hypersonic vehicle with the control law.

Optionally, the longitudinal dynamic model constructing module specifically involves the following Formulas:

$$\dot{V} = \frac{T cosα - D}{m} - g sinγ .$$

$$\dot{γ} = \frac{L + T sinα}{mV} - \frac{g}{V} cosγ ,$$

$$\dot{θ} = q ,$$

$$\dot{q} = \frac{{M}_{yy}}{{I}_{yy}} ,$$

where V represents a speed of the hypersonic vehicle, while γ a flight path angle, q a pitch rate, θ an Euler angle, meeting the relation θ=γ+α with α being an angle of attack, [V, γ, θ, q]^{T} a state vector, T, L, D a thrust, a lift, and a drag, respectively, M_{yy} a pitching moment, m a mass of the hypersonic vehicle, g the gravitational acceleration, and I_{yy} an inertia moment.

Optionally, the longitudinal dynamic model transforming module specifically involves the following Formulas:

\dot{x}₁=f₁+g₁₂u₂, \dot{x}₂=f₂+g₂₁u₁+g₂₂u₂, \dot{x}₃=x₄, \dot{x}₄=f₃+g₃₁u₁+g₃₂u₂,

where x₁ [symbol] x₂ [symbol] x₃ [symbol] x₄ correspondingly take the place of V [symbol] γ [symbol] θ [symbol] q; x₁ and x₂ are output signals, u₁ and u₂ are input signals, and f₁, f₂, f₃, g₁₂, g₂₂, and g₃₂ are coefficients of the transformed longitudinal dynamic model, respectively.

Based on specific embodiments provided in the present disclosure, the present disclosure has the following technical effects: According to a method and system for global stabilization control of a hypersonic vehicle provided in the present disclosure, a longitudinal dynamic model is transformed, and the transformed longitudinal dynamic model includes an output dynamic model and an internal dynamic model; variable decomposition is performed on the transformed longitudinal dynamic model by state decomposition and an auxiliary system model is constructed using decomposed variables, with the auxiliary system model including output dynamics and internal dynamics; subsequently, a control law is determined based on a feedback linearization theory according to the output dynamics. The dependency of internal dynamics on inputs is taken into full account, so that the control law can not only directly stabilize external states of the system but also stabilize unstable internal states. Thus, the present disclosure enables the global stabilization control of a non-minimum phase hypersonic vehicle.

### BRIEF DESCRIPTION OF THE DRAWINGS

To describe the technical solutions in embodiments of the present disclosure or in the prior art more clearly, the accompanying drawings required in the embodiments will be briefly described below. Apparently, the accompanying drawings in the following description show merely some embodiments of the present disclosure, and other drawings can be derived from these accompanying drawings by those of ordinary skill in the art without creative efforts.

FIG. 1 is a flowchart of a method for global stabilization control of a hypersonic vehicle according to the present disclosure.

FIG. 2 is a schematic diagram illustrating system states and input responses when a control law determined in the present disclosure is used in specific Example 1 of the present disclosure.

FIG. 3 is a schematic diagram illustrating system states and input responses when a control law determined in the present disclosure is used in specific Example 2 of the present disclosure.

FIG. 4 is a schematic diagram illustrating simulation results of a control law based on conventional feedback linearization.

FIG. 5 is a schematic diagram illustrating simulation results of a control law based on conventional feedback linearization.

FIG. 6 is a structure diagram of a system for global stabilization control of a hypersonic vehicle according to the present disclosure.

### DETAILED DESCRIPTION

The technical solutions in the embodiments of the present disclosure will be described below clearly and completely with reference to the accompanying drawings in the embodiments of the present disclosure. Apparently, the described embodiments are merely some rather than all of the embodiments of the present disclosure. All other embodiments derived from the embodiments of the present disclosure by a person of ordinary skill in the art without creative efforts shall fall within the protection scope of the present disclosure.

An objective of the present disclosure is to provide a method and system for global stabilization control of a hypersonic vehicle that enable the global stabilization control of a non-minimum phase hypersonic vehicle.

To make the above-mentioned objective, features, and advantages of the present disclosure clearer and more comprehensible, the present disclosure will be further described in detail below in conjunction with the accompanying drawings and specific embodiments.

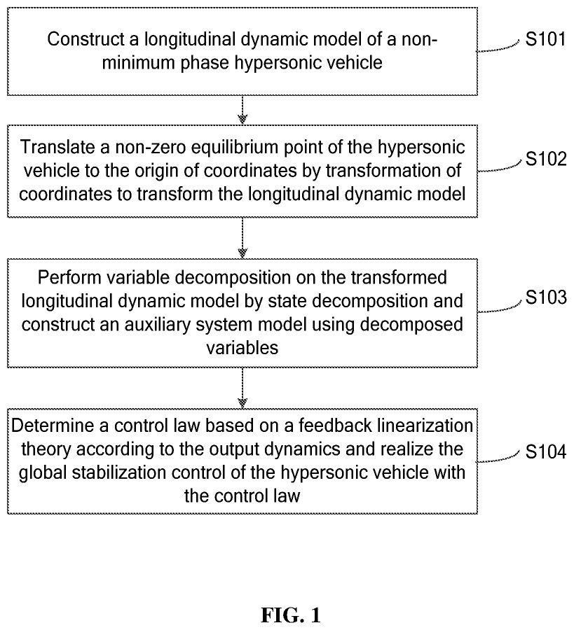

FIG. 1 is a flowchart of a method for global stabilization control of a hypersonic vehicle. As shown in FIG. 1, the method for global stabilization control of a hypersonic vehicle provided in the present disclosure includes:

S101, a longitudinal dynamic model of a non-minimum phase hypersonic vehicle is constructed, where input signals to the longitudinal dynamic model are an elevator angle and a throttle opening, and output signals thereof are a speed and a flight path angle of the hypersonic vehicle.

S101 specifically includes the following Formulas:

$$\dot{V} = \frac{T cosα - D}{m} - g sinγ .$$

$$\dot{γ} = \frac{L + T sinα}{mV} - \frac{g}{V} cosγ ,$$

$$\dot{θ} = q ,$$

$$\dot{q} = \frac{{M}_{yy}}{{I}_{yy}} ,$$

where V represents a speed of the hypersonic vehicle, while γ a flight path angle, q a pitch rate, θ an Euler angle, meeting the relation θ=γ+α with α being an angle of attack, [V, γ, θ, q]^{T} a state vector, T, L, D a thrust, a lift, and a drag, respectively, M_{yy} a pitching moment, m a mass of the hypersonic vehicle, g the gravitational acceleration, and I_{yy} an inertia moment.

Further, L, D, T, M_{yy} meet the following Formulas:

$$L = \frac{1}{2} {ρ V}^{2} {S}_{ref} ( {C}_{L α} + {C}_{L δ} , {δ}_{e} ) ,$$

$$D = \frac{1}{2} {ρ V}^{2} {S}_{ref} {C}_{D α} ,$$

$$T = \frac{1}{2} {ρ V}^{2} {S}_{ref} ( {C}_{T α} + {C}_{T ϕ} ϕ ) ,$$

$${M}_{yy} = {z}_{T} T + \frac{1}{2} {ρ V}^{2} {S}_{ref} \overline{c} ( {C}_{M α} + {C}_{M δ} , {δ}_{e} ) ,$$

where δₑ represents an elevator angle, while ϕ a throttle opening, ρ an air density, and S_{ref} a reference area. Moreover, the following Formulas are also involved:

C_{Lα}=4.6773α−0.018714, C_{Lδ}_{ₑ}=0.076224, C_{Dα}=5.8224α²−0.045315α+0.010131,

C_{Tϕ}=376930α³+26814α²+35542α+6378.5, C_{Tα}=−37225α³−17277α²−2421.6α−100.9,

C_{Mα}=6.2926α²+2.1335α+0.18979, C_{Mδ}_{ₑ}=−1.2897.

S102, a non-zero equilibrium point of the hypersonic vehicle is translated to the origin of coordinates by transformation of coordinates to transform the longitudinal dynamic model, where the transformed longitudinal dynamic model includes an output dynamic model and an internal dynamic model.

[V*, 0, θ*, 0] is assumed to be any equilibrium point of models (1) to (4), and [δ*ₑ, ϕ*] represents the value of [δₑ, ϕ] on the corresponding equilibrium point. Note that the equilibrium point is not unique during the flight of the hypersonic vehicle, i.e., [V*, 0, θ*, 0] and [δ*ₑ, ϕ*] are not unique. According to physical properties, at each equilibrium point, the pitch rate is zero, and the angle of attack is equal to the Euler angle (which means that the track angle is zero), i.e., q=0, γ=0, and α*=θ*. The non-zero equilibrium point of the hypersonic vehicle is translated to the origin of coordinates by transformation of coordinates as follows:

x₁ [symbol] V−V*, x₂ [symbol] γ, x₃ [symbol] θ−θ*, x₄ [symbol] q, u₁ [symbol] δₑ−δ*ₑ, u₂ [symbol] ϕ−ϕ*.

According to a feedback linearization theory, it can be verified that when |α|≤0.35 radian, the hypersonic vehicle model has relative degree [1, 1].

S102 specifically includes the following Formulas:

\dot{x}₁=f₁+g₁₂u₂, \dot{x}₂=f₂+g₂₁u₁+g₂₂u₂, \dot{x}₃=x₄, \dot{x}₄=f₃+g₃₁u₁+g₃₂u₂,

where x₁ [symbol] x₂ [symbol] x₃ [symbol] x₄ correspondingly take the place of V [symbol] γ [symbol] θ [symbol] q; x₁ and x₂ are output signals, u₁ and u₂ are input signals, and f₁, f₂, f₃, g₁₂, g₂₂, and g₃₂ are coefficients of the transformed longitudinal dynamic model, respectively.

\dot{x}₁=f₁+g₁₂u₂, \dot{x}₂=f₂+g₂₁u₁+g₂₂u₂ are output dynamic models, and \dot{x}₃=x₄, \dot{x}₄=f₃+g₃₁u₁+g₃₂u₂ are internal dynamic models,

$${f}_{1} = \frac{{ρ V}^{2} {S}_{ref}}{2 m} ( {C}_{T α} cosα + {C}_{T ϕ} {ϕ}^{*} cosα - {C}_{D α} ) - g sinγ ,$$

$${f}_{2} = \frac{{ρ V S}_{ref}}{2 m} ( {C}_{L α} cosα + {C}_{{L δ}_{e}} {δ}_{e}^{*} + {C}_{T α} sin α + {C}_{T α} sin α + {C}_{T ϕ} {ϕ}^{*} sinα ) - \frac{g cosγ}{V} ,$$

$${f}_{3} = \frac{{ρ V}^{2} {S}_{ref}}{2 {I}_{yy}} ( {z}_{T} {C}_{T α} + {z}_{T} {C}_{T ϕ} {ϕ}^{*} + \overline{c} {C}_{M α} + \overline{c} {C}_{{M δ}_{e}} {δ}_{e}^{*} ) ,$$

$${g}_{12} = \frac{{ρ V}^{2} {S}_{ref} cosα}{2 m} {C}_{T ϕ} ,$$

$${g}_{21} = \frac{{ρ V S}_{ref}}{2 m} {C}_{{L δ}_{e}} ,$$

$${g}_{22} = \frac{{ρ V S}_{ref}}{2 m} {C}_{T ϕ} sin α ,$$

$${g}_{31} = \frac{{ρ V}^{2} {S}_{ref}}{2 m} \overline{c} {C}_{{M δ}_{e}} ,$$

$${g}_{32} = \frac{{ρ V}^{2} {S}_{ref}}{2 {I}_{yy}} {z}_{T} {C}_{T ϕ} ,$$

$$α = {x}_{3} + {θ}^{*} - {x}_{2} .$$

$$where$$

The transformed longitudinal dynamic model is a non-minimum phase model. According to the feedback linearization theory, system zero dynamics are defined as internal dynamics when system output signals are constantly zero. To verify that the internal dynamic models are unstable, system output signals are assumed to be x₁=x₂=0, and in this case, the system input signals are

$${u}_{1} = \frac{{g}_{22} {f}_{1}}{{g}_{12} {g}_{21}} - \frac{{f}_{2}}{{g}_{21}} and {u}_{2} = - \frac{{f}_{1}}{{g}_{12}} .$$

The Formulas of the input signals are substituted into \dot{x}₄=f₃+g₃₁u₁+g₃₂u₂ to obtain the following zero dynamic equation of the hypersonic vehicle:

$${\dot{x}}_{3} = {x}_{4} , \\ {\dot{x}}_{4} = {f}_{3} + \frac{{g}_{31} {g}_{22} {f}_{1}}{{g}_{12} {g}_{21}} - \frac{{g}_{31} {f}_{2}}{{g}_{21}} - \frac{{g}_{32} {f}_{1}}{{g}_{12}} .$$

Jacobian matrix at the origin is as follows:

$$[ \begin{matrix}0 & 1 \\ \frac{\partial ( {f}_{3} + \frac{{g}_{31} {g}_{22} {f}_{1}}{{g}_{12} {g}_{21}} - \frac{{g}_{31} {f}_{2}}{{g}_{21}} - \frac{{g}_{32} {f}_{1}}{{g}_{12}} )}{\partial θ} & 0\end{matrix} ] .$$

From the physical values in the above Formula, it can be calculated that one characteristic value of the matrix has positive real part, and the characteristic value with positive real part is an unstable characteristic value. That is, the linearized internal dynamic at the origin are unstable. Therefore, it is verified that the hypersonic vehicle model is a non-minimum phase model.

S103, variable decomposition is performed on the transformed longitudinal dynamic model by state decomposition, and an auxiliary system model is constructed using decomposed variables, where the auxiliary system model includes output dynamics and internal dynamics.

The sum of two signals s and N is used in constructing the auxiliary system model with the decomposed variables,

where s will be set to a virtual output signal, and N will be used to compensate the unstable internal dynamics to stabilize the internal dynamics; and it is assumed that xᵢ=sᵢ+Nᵢ and i=1, 2 (**).

The system input signals u₁, u₂ always meet the equation [u₁, u₂]^{T}=G⁻¹[\dot{N}₁+\dot{s}₁−f₁, \dot{N}₂+\dot{s}₂−f₂]^{T}. To eliminate the control input signals in the equations of the internal dynamic models, the following Formulas are derived from the identical equation:

$${\dot{s}}_{1} = {f}_{1} + {g}_{12} {u}_{2} - {\dot{N}}_{1} , \\ {\dot{s}}_{2} = {f}_{2} + {g}_{21} {u}_{1} + {g}_{22} {u}_{2} - {\dot{N}}_{2} , \\ {\dot{x}}_{3} = {x}_{4} , \\ {\dot{x}}_{4} = {f}_{3} + \frac{{g}_{31}}{{g}_{21}} ( {\dot{s}}_{2} + {\dot{N}}_{2} - {f}_{2} ) + \frac{{g}_{32} {g}_{21} - {g}_{31} {g}_{22}}{{g}_{12} {g}_{21}} ( {\dot{s}}_{1} + {\dot{N}}_{1} - {f}_{1} ) ,$$

where s₁, s₂ are output signals; N1 and N2 are designed compensation control signals, with

$${\dot{N}}_{1} = - {γ}_{1} {N}_{1} + {f}_{1} - \frac{{g}_{12} {g}_{21}}{{g}_{32} {g}_{21} - {g}_{31} {g}_{22}} ( {f}_{3} + {λ}_{11} {x}_{4} + {λ}_{10} {x}_{3} + \frac{{g}_{31}}{{g}_{21}} ( - {μ}_{2} {s}_{2} - {γ}_{2} {N}_{2} - {f}_{2} ) )$$

and \dot{N}₂=−γ₂N₂; γ₁, γ₂, λ₁₁, and λ₁₀ are all constant coefficients, with γ₁ and γ₂ being greater than zero and λ₁₁ and λ₁₀ meeting a stable polynomial z²+λ₁₁z+λ₁₀ with respect to z; and g₂₁ and g₃₁ are model coefficients.

Specifically, \dot{s}₁=f₁+g₁₂u₂−\dot{N}₁, \dot{s}₂=f₂+g₂₁u₁+g₂₂u₂−\dot{N}₂ are output dynamics, and

$${\dot{x}}_{3} = {x}_{4} , \\ {\dot{x}}_{4} = {f}_{3} + \frac{{g}_{31}}{{g}_{21}} ( {\dot{s}}_{2} + {\dot{N}}_{2} - {f}_{2} ) + \frac{{g}_{32} {g}_{21} - {g}_{31} {g}_{22}}{{g}_{12} {g}_{21}} ( {\dot{s}}_{1} + {\dot{N}}_{1} - {f}_{1} )$$

are internal dynamics.

S104, a control law is determined based on the feedback linearization theory according to the output dynamics, and the global stabilization control of the hypersonic vehicle is realized with the control law.

S104 specifically includes the following Formula:

$$[ \begin{matrix}{u}_{1} \\ {u}_{2}\end{matrix} ] = {G}^{- 1} [ \begin{matrix}- {f}_{1} - {μ}_{1} {x}_{1} + {μ}_{1} {N}_{1} + {\dot{N}}_{1} \\ - {f}_{2} - {μ}_{2} {x}_{2} + {μ}_{2} {N}_{2} + {\dot{N}}_{2}\end{matrix} ] ,$$

where G is an output coefficient matrix:

$$G = [ \begin{matrix}0 & {g}_{12} \\ {g}_{21} & {g}_{22}\end{matrix} ] .$$

When the angle of attack meets |α|≤0.35 radian, G is nonsingular. When the angle of attack is around α=0.4 radian, the output coefficient matrix G is singular (the determinant is zero).

According to the physical meaning of system signals, the initial values Nᵢ₀, sᵢ₀ of Nᵢ, sᵢ are required to meet Nᵢ₀+sᵢ₀=xᵢ₀, with xᵢ₀ representing the initial value of xᵢ, i=1, 2. The control law (31) is substituted into the auxiliary model to obtain:

\dot{s}ᵢ=−μᵢsᵢ, i=1,2.

This indicates that the control law can guarantee that the virtual signal sᵢ exponentially converges, and meanwhile, it can be verified that Nᵢ also exponentially converges and hence x₁, x₂. Moreover, \dot{x}₄+λ₁₁x₄+λ₁₀x₃=ε, where ε is an exponential attenuation term depending on a system initial value. Thus, according to the physical relation of x₃, x₄, it can be seen that x₃, x₄ also exponentially converge. Therefore, the states of the whole closed-loop system all exponentially converge.

Hereinafter, the present disclosure is simulated by way of specific examples, and the effects of the present disclosure are further explained with the simulation results.

The units of ρ, m, S_{ref}, z_{T}, I_{yy} are omitted, and their respective quantitative values are as follows: ρ=5×10⁻⁵, m=300, S_{ref}=17, z_{T}=8.36, I_{yy}=5×10⁵, c̅=17. The equilibrium points of the hypersonic vehicle model are calculated as follows: x*ₑ=[7000 ft/s, 0 rad, 0.1639 rad, 0 rad/s]^{T}, δ*ₑ=0.2, and ϕ*=0.1.

The effectiveness of the proposed control law is verified below using two solutions.

Example 1, the initial values of the state variables are as follows:
V(0)=7200 ft/s, γ(0)=−0.01 rad, θ(0)=0.1689 rad, q(0)=−0.05 rad/s, N₁(0)=100,
s₁(0)=100, N₂(0)=0, s₂(0)=γ(0).

### Example 2,

V(0)=6800 ft/s, γ(0)=0.01 rad,
θ(0)=0.1539 rad, q(0)=0.05 rad/s, N₁(0)=−100, s₁(0)=−100, N₂(0)=0, s₂(0)=γ(0)_{∘} N₂ is redundant, and therefore, N₂(0) is set as 0.

For the two Examples, let γ₁=γ₂=1, u₁=1, u₂=0.1.

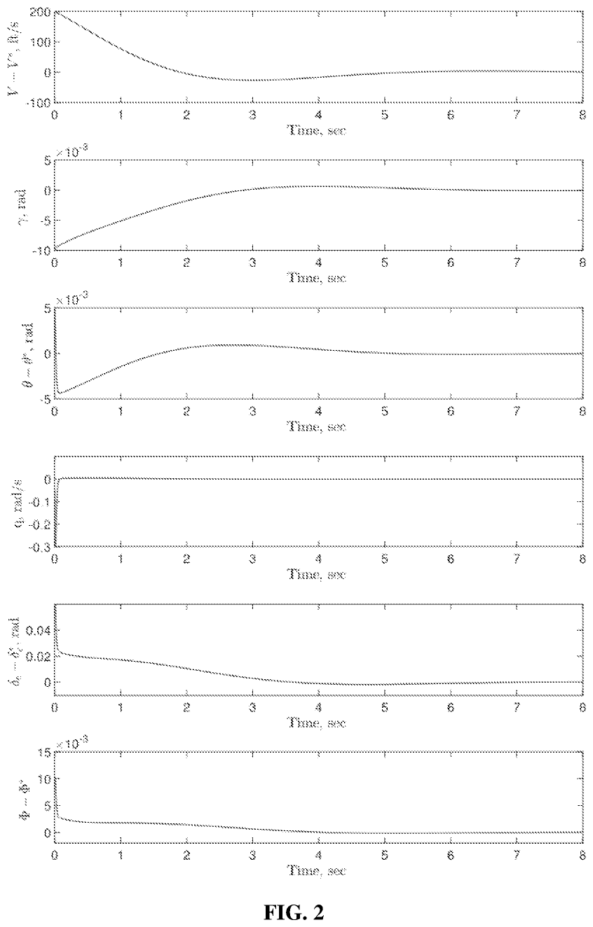

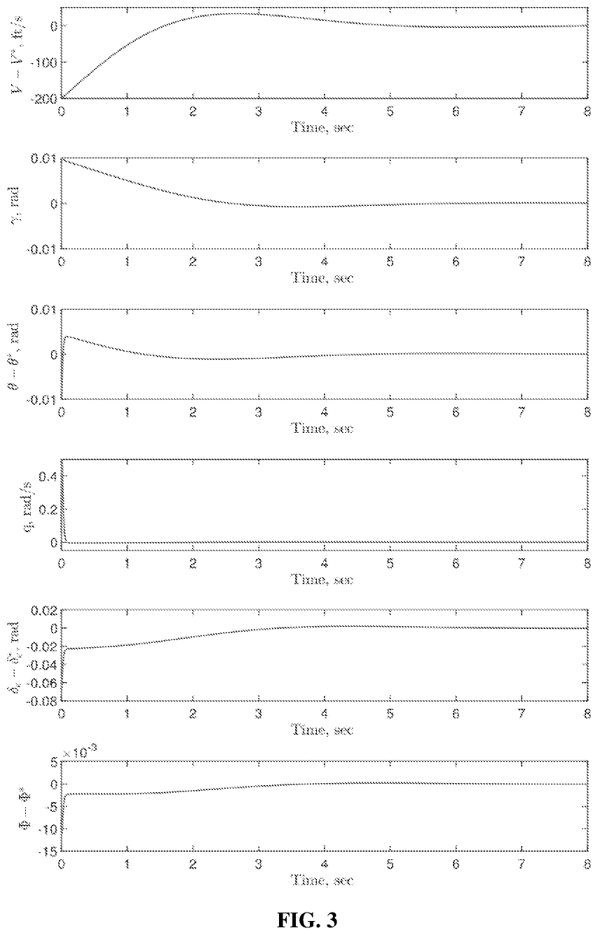

When the control law is used, FIG. 2 and FIG. 3 show the system states and input responses of Example 1 and Example 2, respectively. From the two figures, with the two solutions, the simulation results all converge to stable x*ₑ. This indicates that the proposed control algorithm is independent of system initial values.

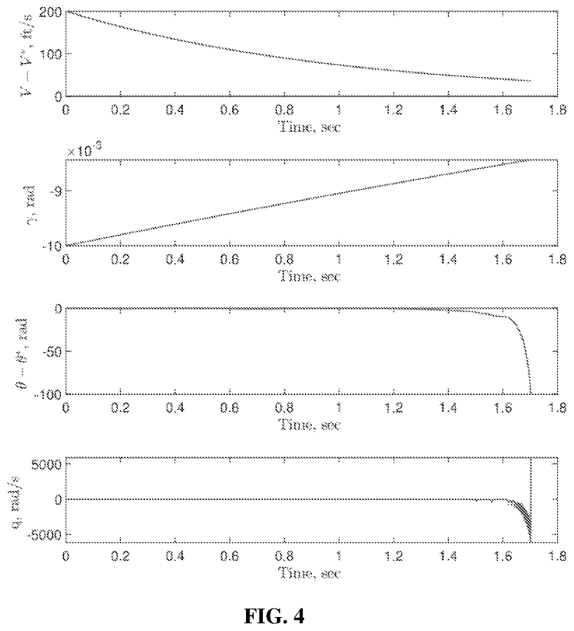

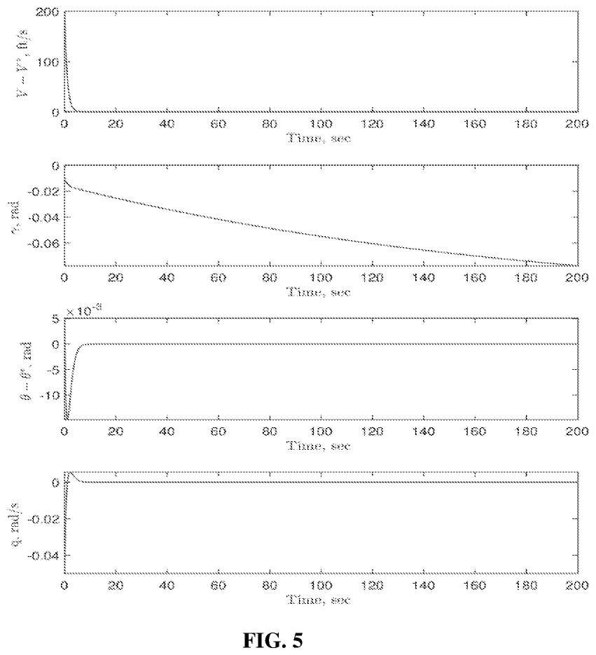

As a contrast, some simulation results for the control law based on conventional feedback linearization are given below. FIG. 4 and FIG. 5 show the system state responses when u=G⁻¹[−μ₁x₁−f₁,−μ₂x₂−f₂]^{T}, u=G₂⁻¹[−μ₁x₁−f₁,−μ₂x₂−f₂]^{T}, and

$${G}_{2} = [ \begin{matrix}0 & {g}_{12} \\ {g}_{31} & {g}_{32}\end{matrix} ] ,$$

respectively.

As shown in FIG. 4 and FIG. 5, the simulation results for the control law based on conventional feedback linearization indicate that the control law can effectively stabilize the external dynamics of the system. However, since the hypersonic system is a typical non-minimum phase system (i.e., unstable internal dynamics), the control law based on feedback linearization cannot stabilize the internal dynamics, resulting in that the whole closed-loop system is unstable.

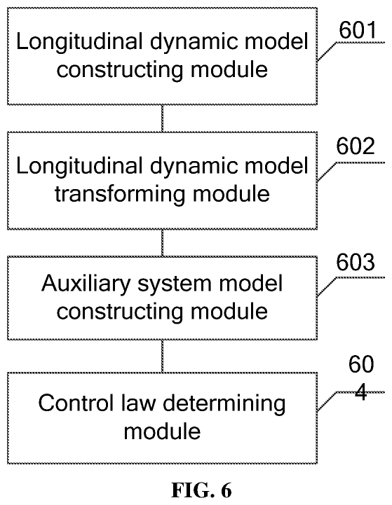

FIG. 6 is a schematic diagram of a system for global stabilization control of a hypersonic vehicle. As shown in FIG. 6, the system for global stabilization control of a hypersonic vehicle provided in the present disclosure includes: a longitudinal dynamic model constructing module 601 configured to construct a longitudinal dynamic model of a non-minimum phase hypersonic vehicle, where input signals to the longitudinal dynamic model are an elevator angle and a throttle opening, and output signals thereof are a speed and a flight path angle of the hypersonic vehicle; a longitudinal dynamic model transforming module 602 configured to translate a non-zero equilibrium point of the hypersonic vehicle to the origin of coordinates by transformation of coordinates to transform the longitudinal dynamic model, where the transformed longitudinal dynamic model includes an output dynamic model and an internal dynamic model; an auxiliary system model constructing module 603 configured to perform variable decomposition on the transformed longitudinal dynamic model by state decomposition and construct an auxiliary system model using decomposed variables, where the auxiliary system model includes output dynamics and internal dynamics; and a control law determining module 604 configured to determine a control law based on a feedback linearization theory according to the output dynamics and realize the global stabilization control of the hypersonic vehicle with the control law.

The longitudinal dynamic model constructing module 601 specifically includes the following Formulas:

$$\dot{V} = \frac{T cos α - D}{m} - g sin γ , \\ \dot{γ} = \frac{L + T sin α}{m V} - \frac{g}{V} cos γ , \\ \dot{θ} = q , \\ \dot{q} = \frac{{M}_{yy}}{{I}_{y y}} ,$$

where V represents a speed of the hypersonic vehicle, while γ a flight path angle, q a pitch rate, θ an Euler angle, meeting the relation θ=γ+α with α being an angle of attack, [V, γ, θ, q]^{T} a state vector, T, L, D a thrust, a lift, and a drag, respectively, M_{yy} a pitching moment, m a mass of the hypersonic vehicle, g the gravitational acceleration, and I_{yy} an inertia moment.

The longitudinal dynamic model transforming module 602 specifically includes the following Formulas:

\dot{x}₁=f₁+g₁₂u₂, \dot{x}₂=f₂+g₂₁u₁+g₂₂u₂, \dot{x}₃=x₄, \dot{x}₄=f₃+g₃₁u₁+g₃₂u₂,

where x₁ [symbol] x₂ [symbol] x₃ [symbol] x₄ correspondingly take the place of V [symbol] γ [symbol] θ [symbol] q; x₁ and x₂ are output signals, u₁ and u₂ are input signals, and f₁, f₂, f₃, g₁₂, g₂₂, and g₃₂ are coefficients of the transformed longitudinal dynamic model, respectively.

The embodiments are described herein in a progressive manner. Each embodiment focuses on the difference from another embodiment, and the same and similar parts between the embodiments may refer to each other. Since the system disclosed in an embodiment corresponds to the method disclosed in another embodiment, the description is relatively simple, and reference can be made to the method description.

Specific examples are used herein to explain the principles and embodiments of the present disclosure. The foregoing description of the embodiments is merely intended to help understand the method of the present disclosure and its core ideas; besides, various modifications may be made by a person of ordinary skill in the art to specific embodiments and the scope of application in accordance with the ideas of the present disclosure. In conclusion, the content of the present description shall not be construed as limitations to the present disclosure.

What is claimed is:

1. A method for global stabilization control of a hypersonic vehicle, comprising:
constructing a longitudinal dynamic model of a non-minimum phase hypersonic vehicle, wherein the longitudinal dynamic model uses an elevator angle and a throttle opening as input signals, and a speed and a flight path angle of the hypersonic vehicle as output signals;
translating a non-zero equilibrium point of the hypersonic vehicle to the origin of coordinates by transformation of coordinates to transform the longitudinal dynamic model, wherein the transformed longitudinal dynamic model comprises an output dynamic model and an internal dynamic model;
performing variable decomposition on the transformed longitudinal dynamic model by state decomposition and constructing an auxiliary system model using decomposed variables, wherein the auxiliary system model comprises output dynamics and internal dynamics; and
determining a control law based on a feedback linearization theory according to the output dynamics and realizing the global stabilization control of the hypersonic vehicle with the control law.

2. The method for global stabilization control of a hypersonic vehicle according to claim 1, wherein the constructing a longitudinal dynamic model of a non-minimum phase hypersonic vehicle specifically involves the following Formulas:
$$\dot{V} = \frac{T cos α - D}{m} - g sin γ , \\ \dot{γ} = \frac{L + T sin α}{m V} - \frac{g}{V} cos γ , \\ \dot{θ} = q , \\ \dot{q} = \frac{{M}_{y y}}{{I}_{yy}} ,$$
wherein V represents a speed of the hypersonic vehicle, while γ a flight path angle, q a pitch rate, θ an Euler angle, meeting the relation θ=γ+α with α being an angle of attack, [V, γ, θ, q]^{T} a state vector, T, L, D a thrust, a lift, and a drag, respectively, M_{yy} a pitching moment, m a mass of the hypersonic vehicle, g the gravitational acceleration, and I_{yy} an inertia moment.

3. The method for global stabilization control of a hypersonic vehicle according to claim 2, wherein the translating a non-zero equilibrium point of the hypersonic vehicle to the origin of coordinates by transformation of coordinates to transform the longitudinal dynamic model is specifically involves the following Formulas:
\dot{x}₁=f₁+g₁₂u₂, \dot{x}₂=f₂+g₂₁u₁+g₂₂u₂, \dot{x}₃=x₄, \dot{x}₄=f₃+g₃₁u₁+g₃₂u₂,
wherein x₁ [symbol] x₂ [symbol] x₃ [symbol] x₄ correspondingly take the place of V [symbol] γ [symbol] θ [symbol] q; x₁ and x₂ are output signals, u₁ and u₂ are input signals, and f₁, f₂, f₃, g₁₂, g₂₂, and g₃₂ are coefficients of the transformed longitudinal dynamic model, respectively.

4. The method for global stabilization control of a hypersonic vehicle according to claim 3, wherein the performing variable decomposition on the transformed longitudinal dynamic model by state decomposition and constructing an auxiliary system model using decomposed variables specifically involves the following Formulas:
$${\dot{s}}_{1} = {f}_{1} + {g}_{12} {u}_{2} - {\dot{N}}_{1} , \\ {\dot{s}}_{2} = {f}_{2} + {g}_{21} {u}_{1} + {g}_{22} {u}_{2} - {\dot{N}}_{2} , \\ {\dot{x}}_{3} = {x}_{4} , {\dot{x}}_{4} = {f}_{3} + \frac{{g}_{31}}{{g}_{21}} ( {\dot{s}}_{2} + {\dot{N}}_{2} - {f}_{2} ) + \frac{{g}_{32} {g}_{21} - {g}_{31} {g}_{22}}{{g}_{12} {g}_{21}} ( {\dot{s}}_{1} + {\dot{N}}_{1} - {f}_{1} ) ,$$
wherein s₁, s₂ are output signals; N₁ and N₂ are designed compensation control signals, with
$${\dot{N}}_{1} = - {γ}_{1} {N}_{1} + {f}_{1} - \frac{{g}_{12} {g}_{21}}{{g}_{32} {g}_{21} - {g}_{31} {g}_{22}} ( {f}_{3} + {λ}_{11} {x}_{4} + {λ}_{10} {x}_{3} + \frac{{g}_{31}}{{g}_{21}} ( - {μ}_{2} {s}_{2} - {γ}_{2} {N}_{2} - {f}_{2} ) )$$
and \dot{N}₂=−γ₂N₂; γ₁, γ₂, λ₁₁, and λ₁₀ are all constant coefficients, with γ₁ and γ₂ being greater than zero and λ₁₁ and λ₁₀ meeting a stable polynomial z²+λ₁₁z+λ₁₀ with respect to z; and g₂₁ and g₃₁ are model coefficients.

5. The method for global stabilization control of a hypersonic vehicle according to claim 4, wherein the determining a control law based on a feedback linearization theory according to the output dynamics and realizing the global stabilization control of the hypersonic vehicle with the control law specifically involve the following Formula:
$$[ \begin{matrix}{u}_{1} \\ {u}_{2}\end{matrix} ] = {G}^{- 1} [ \begin{matrix}- {f}_{1} - {μ}_{1} {x}_{1} + {μ}_{1} {N}_{1} + {\dot{N}}_{1} \\ - {f}_{2} - {μ}_{2} {x}_{2} + {μ}_{2} {N}_{2} + {\dot{N}}_{2}\end{matrix} ] ,$$
wherein G is an output coefficient matrix.

6. A system for global stabilization control of a hypersonic vehicle, comprising:
a longitudinal dynamic model constructing module, configured to construct a longitudinal dynamic model of a non-minimum phase hypersonic vehicle, wherein input signals to the longitudinal dynamic model are an elevator angle and a throttle opening, and output signals thereof are a speed and a flight path angle of the hypersonic vehicle;
a longitudinal dynamic model transforming module, configured to translate a non-zero equilibrium point of the hypersonic vehicle to the origin of coordinates by transformation of coordinates to transform the longitudinal dynamic model, wherein the transformed longitudinal dynamic model comprises an output dynamic model and an internal dynamic model;
an auxiliary system model constructing module, configured to perform variable decomposition on the transformed longitudinal dynamic model by state decomposition and construct an auxiliary system model using decomposed variables, wherein the auxiliary system model comprises output dynamics and internal dynamics; and
a control law determining module, configured to determine a control law based on a feedback linearization theory according to the output dynamics and realize the global stabilization control of the hypersonic vehicle with the control law.

7. The system for global stabilization control of a hypersonic vehicle according to claim 6, wherein the longitudinal dynamic model constructing module specifically involves the following Formulas:
$$\dot{V} = \frac{T cos α - D}{m} - g sin γ , \\ \dot{γ} = \frac{L + T sin α}{m V} - \frac{g}{V} cos γ , \\ \dot{θ} = q , \\ \dot{q} = \frac{{M}_{y y}}{{I}_{y y}} ,$$
wherein V represents a speed of the hypersonic vehicle, while γ a flight path angle, q a pitch rate, θ an Euler angle, meeting the relation θ=γ+α with α being an angle of attack, [V, γ, θ, q]^{T} a state vector, T, L, D a thrust, a lift, and a drag, respectively, M_{yy} a pitching moment, m a mass of the hypersonic vehicle, g the gravitational acceleration, and I_{yy} an inertia moment.

8. The system for global stabilization control of a hypersonic vehicle according to claim 7, wherein the longitudinal dynamic model transforming module specifically involves the following Formulas:
\dot{x}₁=f₁+g₁₂u₂, \dot{x}₂=f₂+g₂₁u₁+g₂₂u₂, \dot{x}₃=x₄, \dot{x}₄=f₃+g₃₁u₁+g₃₂u₂,
wherein x₁ [symbol] x₂ [symbol] x₃ [symbol] x₄ correspondingly take the place of V [symbol] γ [symbol] θ [symbol] q; x₁ and x₂ are output signals, u₁ and u₂ are input signals, and f₁, f₂, f₃, g₁₂, g₂₂, and g₃₂ are coefficients of the transformed longitudinal dynamic model, respectively. f_{f}
